(19) United States
(12) Patent Application Publication
(10) Pub. No.: US 2012/0112939 A1
(43) Pub. Date: May 10, 2012

(54) PIPELINE AD CONVERTER AND METHOD OF CORRECTING OUTPUT FROM THE CONVERTER

(75) Inventors: Takuji MIKI, Kyoto (JP); Takashi Morie, Osaka (JP)

(73) Assignee: PANASONIC CORPORATION, Osaka (JP)

(21) Appl. No.: 13/351,933

(22) Filed: Jan. 17, 2012

Related U.S. Application Data
(63) Continuation of application No. PCT/JP2009/006024, filed on Nov. 11, 2009.

(30) Foreign Application Priority Data
Aug. 18, 2009 (JP) 2009-189366

(51) Int. Cl. H03M 1/06

(52) U.S. Cl. 341/118

(57) ABSTRACT

A digital correction circuit calculates AD conversion errors EA and EA′ in AD conversion stages subsequent to a target stage of AD conversion. EA is an error between an AD conversion result when a digital output of the target stage is set to 0, and an AD conversion result when it is set to +1 in a state where a higher reference voltage is input to the target stage. EB is an error between an AD conversion result when the digital output is set to 0, and an AD conversion result when it is set to −1 in a state where a lower reference voltage is input to the target stage. The digital correction circuit adds a correcting value of the target stage to the digital output. The correcting value is −(EA+EB)/2 when the digital output is −1, −(EA−EB)/2 when it is 0, and +(EA+EB)/2 when it is +1.

### CROSS-REFERENCE TO RELATED APPLICATION

This is a continuation of PCT International Application PCT/JP2009/006024 filed on Nov. 11, 2009, which claims priority to Japanese Patent Application No. 2009-189366 filed on Aug. 18, 2009. The disclosures of these applications including the specifications, the drawings, and the claims are hereby incorporated by reference in their entirety.

### BACKGROUND

The present disclosure relates to pipeline AD converters, and more particularly to digital correction of outputs from pipeline AD converters.

In the field of signal processing, AD converters converting analog signals to digital signals are often used. There are various types of AD converters, which include pipeline AD converters. A pipeline AD converter includes a plurality of AD conversion stages coupled in cascade. Each AD conversion stage outputs a digital value of 1 bit or several bits based on the result of magnitude comparison between an input voltage and one or more reference voltages, and amplifies and outputs the residual voltage obtained by subtracting a voltage corresponding to the digital value from the input voltage. The digital values output from the AD conversion stages are summed while shifting the bit positions of the digital values, thereby performing AD conversion of a large number of bits.

In the past, the accuracy of pipeline AD converters has been obtained by utilizing capacitive elements with high ratio accuracy and high-gain characteristics of operational amplifiers. In other words, higher accuracy of pipeline AD converters has been obtained by higher performance and higher accuracy of analog circuits. However, as miniaturization of LSI processes progress in recent years, reduction in areas and power consumption of analog circuits using miniaturized elements has been required. Therefore, it becomes difficult to increase the accuracy of pipeline AD converters by improving analog characteristics. Correction in the digital domain such as addition of correcting values obtained by quantizing amplification errors in residual voltages in AD conversion stages to an actual AD converted value is employed. (See, for example, U.S. Pat. No. 5,499,027 and U.S. Pat. No. 6,369,744). As such, nonlinear errors in the AD conversion stages are corrected in the digital domain. This provides a highly accurate pipeline AD converter using an analog circuit which requires a small area or low power consumption, although the conversion accuracy is low. Furthermore, correction of offset errors such that a median of an analog input range is not converted to a median of a digital output range due to an error in a reference voltage, in the digital domain is also suggested. (See, for example, Japanese Patent Publication No. 2006-109403).

Another type performs double sampling by operating two pipeline AD converters in parallel (see, for example, Sumanen, L.; Waltari, M.; Halonen, K., A 10-bit 200 MS/s CMOS parallel pipeline A/D converter, Solid-State Circuits Conference, 2000, ESSCIRC '00. Proceedings of the 26th European, 19-21 Sepember 2000, pp. 439-442). There is also a type alternately using an operational amplifier for amplifying residual voltages between two AD conversion stages (see, for example, Nagaraj, K.; Fetterman, H. S.; Shariatdoust, R. S.; Anidjar, J.; Lewis, S. H.; Alsayegh, J.; Renninger, R. G., An 8-bit 50+ Msamples/s pipelined A/D converter with an area and power efficient architecture, Custom Integrated Circuits Conference, 1996, Proceedings of the IEEE 1996, 5-8 May 1996, pp. 423-426). In single sampling not sharing an operational amplifier, timing for resetting a residual charge at an input node of the operational amplifier can be obtained in every one-clock cycle. On the other hand, such timing cannot be obtained in the configuration with a shared amplifier, which performs the above-described double sampling or alternately uses an operational amplifier, since the operational amplifier is shared by a plurality of AD conversion stages. This leads to a memory effect error caused by a memory effect of the common operational amplifier. In particular, when the gain of the common operational amplifier is small, the amplifier is largely influenced by the memory effect. Thus, another type is suggested, which includes two operational amplifiers shared by two AD conversion stages to cancel residual charges at input nodes in the two shared operational amplifiers in the analog domain by switching an inverting input and a non-inverting input of one of the operational amplifiers in every one-clock cycle. (See, for example, U.S. Pat. No. 7,304,598)

In the conventional offset error correction, analog value 0 is input to AD conversion stages as a median of an analog input range, and an error from the median is treated as an offset correcting value. The step of inputting the analog value 0 is additionally required for the offset error correction. Therefore, in the conventional offset error correction, a circuit configuration for generating analog value 0 is needed, and in addition, the correction time is increased by including the additional step.

On the other hand, with respect to output correction in a pipeline AD converter with a shared amplifier, a memory effect error cannot be corrected simply by employing conventional correction in the digital domain. The conventional correction in the digital domain can correct the following: gain shortage in the operational amplifier, AD conversion errors caused by manufacturing variations in capacitive elements and variations in reference voltages, i.e., static AD conversion errors independent from data. In the above-described correction in the analog domain, memory effect errors, i.e., AD conversion errors dependent on data can be corrected. However, a switch for switching outputs from the operational amplifiers needs to be provided extra since the two operational amplifiers are alternately used. This results in not only an increase in the area of the circuit and power consumption, but also an increase in parasitic elements at output nodes of the operational amplifiers.

### SUMMARY

The present invention is advantageous in correcting an AD conversion error in the digital domain using a pipeline AD converter of each type of: a configuration for single sampling and a configuration with a shared amplifier.

A pipeline AD converter according to one aspect of the present disclosure includes: a plurality of cascade-coupled AD conversion stages, each configured to output as a digital output, a value represented in redundant binary according to a magnitude relationship between an input voltage and two reference voltages, a higher and a lower reference voltages, and to output a voltage obtained by subtracting a voltage corresponding to the digital output from the input voltage and doubling; and a digital correction circuit configured to calculate AD conversion errors EA and EB in AD conversion stages subsequent to a target stage which is one of the plurality of AD conversion stages. EA is an error between an AD conversion result when the digital output of the target stage is set to 0, and an AD conversion result when the digital output of the target stage is set to +1 in a state where the higher reference voltage is input to the target stage. EB is an error between an AD conversion result when the digital output of the target stage is set to 0, and an AD conversion result when the digital output of the target stage is set to −1 in a state where the lower reference voltage is input to the target stage. The digital correction circuit adds a correcting value of the target stage to the digital output of the target stage. The correcting value is −(EA+EB)/2 where the digital output of the target stage is −1, −(EA−EB)/2 where the digital output of the target stage is 0, and +(EA+EB)/2 where the digital output of the target stage is +1.

This configuration enables correction of nonlinear errors and offset errors in AD conversion stages in the digital domain. In addition, there is no need to input analog value 0 to the AD conversion stages to calculate offset correcting values.

A pipeline AD converter according to another aspect includes a plurality of cascade-coupled AD conversion stages, each configured to output as a digital output, a value represented in redundant binary according to a magnitude relationship between an input voltage and two reference voltages, a higher and a lower reference voltages, and to output a voltage obtained by subtracting a voltage corresponding to the digital output from the input voltage and doubling; and a digital correction circuit configured to calculate AD conversion errors EA and EA′ in AD conversion stages subsequent to a target stage which is one of the plurality of AD conversion stages and alternately uses a common operational amplifier with another AD conversion stage. EA is an error between an AD conversion result when two or more clock cycles have passed after setting the digital output of the target stage to 0, and an AD conversion result when two or more clock cycles have passed after setting the digital output of the target stage to +1 in a state where the higher reference voltage is input to the target stage. EA′ is an error between an AD conversion result when the digital output of the target stage is changed from +1 to 0, and an AD conversion result when the digital output of the target stage is changed from 0 to +1 in a state where the higher reference voltage is input to the target stage. The digital correction circuit subtracts a correcting value of the target stage from the digital output of the target stage. The correcting value is a value obtained by multiplying an output from the AD conversion stages subsequent to the target stage one clock earlier by (EA−EA′)/(EA+EA′).

This configuration enables correction of memory effect errors in AD conversion stages in the pipeline AD converter with the shared amplifier in the digital domain.

Preferably, in the above pipeline AD converter, the digital correction circuit calculates an AD conversion error EB in the AD conversion stages subsequent to the target stage. EB is preferably an error between an AD conversion result when two or more clock cycles have passed after setting the digital output of the target stage to 0, and an AD conversion result when two or more clock cycles have passed after setting the digital output of the target stage to −1 in a state where the lower reference voltage is input to the target stage. The digital correction circuit preferably adds a correcting value of the target stage to the digital output of the target stage. The correcting value is −(EA+EB)(1−γ)/2 where the digital output of the target stage is −1, −(EA−EB)(1−γ)/2 where the digital output of the target stage is 0, and +(EA+EB)(1−γ)/2 where the digital output of the target stage is +1, where γ=(EA−EA′)/(EA+EA′).

This configuration enables correction of nonlinear errors and offset errors in AD conversion stages in the pipeline AD converter with the shared amplifier in the digital domain. In addition, there is no need to input analog value 0 to the AD conversion stages to calculate offset correcting values.

### BRIEF DESCRIPTION OF THE DRAWINGS

FIG. 1 illustrates a configuration of a pipeline AD converter according to a first embodiment.

FIG. 2 is a graph illustrating analog input/output characteristics of an AD conversion stage.

FIG. 3 is a graph illustrating AD conversion characteristics of an AD conversion stage before and after linearity correction.

FIG. 4 is a graph illustrating conversion characteristics of an AD conversion stage where an error occurs in a reference voltage.

FIG. 5 illustrates a partial configuration of a pipeline AD converter with a shared amplifier according to a second embodiment.

FIG. 6 is a graph illustrating a change pattern of an output voltage of an AD conversion stage sharing an amplifier.

FIG. 7 is another graph illustrating a change pattern of an output voltage of an AD conversion stage sharing an amplifier.

FIG. 8 is still another graph illustrating a change pattern of an output voltage of an AD conversion stage sharing an amplifier.

### DETAILED DESCRIPTION

### First Embodiment

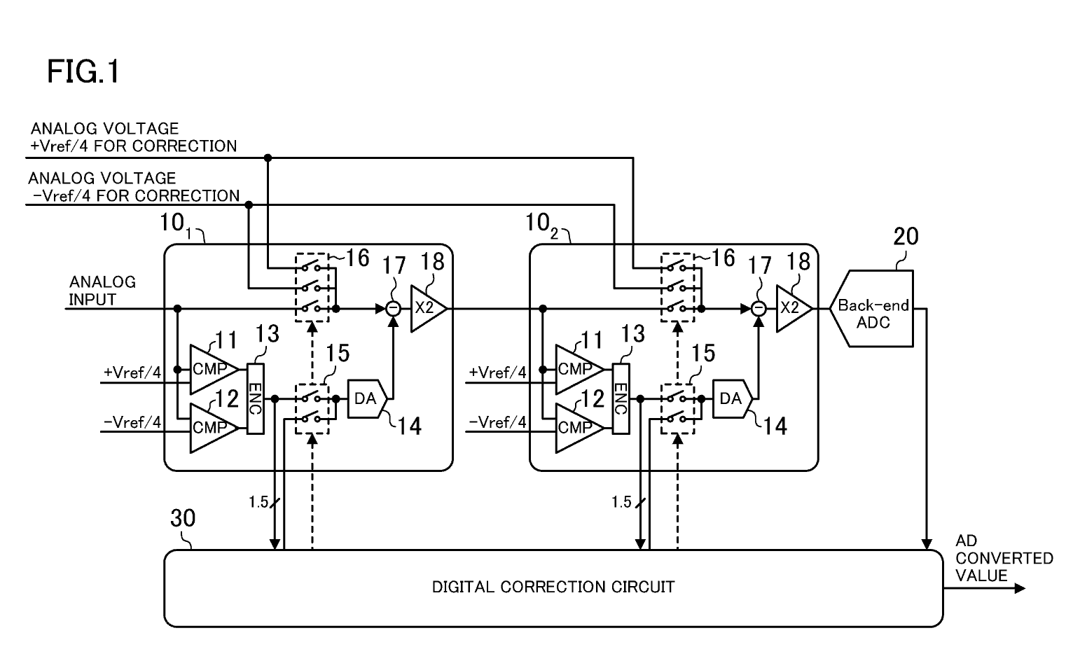

FIG. 1 illustrates a pipeline AD converter according to a first embodiment. The pipeline AD converter according to this embodiment includes AD conversion stages 10 and 20 which are coupled in cascade, and a digital correction circuit 30. The reference characters for the AD conversion stages 10 may be subscripted to specify the individual stages.

Each of the AD conversion stages 10 is an AD converter with 1.5-bit redundancy. An analog input to the AD conversion stage 10 ranges from −Vref to +Vref. In the AD conversion stage 10, comparators 11 and 12 compare a stage input voltage to +Vref/4 and −Vref/4, respectively. An encoder 13 outputs a 2-bit value based on the comparison results of the comparators 11 and 12. The encoder 13 outputs a 2-bit value (e.g., “00”) representing −1 when the stage input voltage is smaller than −Vref/4, a 2-bit value (e.g., “01”) representing 0 when the stage input voltage ranges from −Vref/4 to +Vref/4, and a 2-bit value (e.g., “10”) representing +1 when the stage input voltage is greater than +Vref/4.

A DA converter 14 outputs a voltage corresponding to an input digital value. Specifically, the DA converter 14 outputs −Vref when the 2-bit value representing −1 is input, 0 when the 2-bit value representing 0 is input, and +Vref when the 2-bit value representing +1 is input. A switch circuit 15 inputs either one of the output signal of the encoder 13, or a DAC control signal from the digital correction circuit 30 to the DA converter 14.

A switch circuit 16 outputs one of the three of: the stage input voltage, +Vref/4, and −Vref/4. A difference circuit 17 generates the difference voltage between the output voltage of the switch circuit 16 and the output voltage of the DA converter 14. An amplifier circuit 18 amplifiers the difference voltage by a factor of two. That is, each of the AD conversion stages 10 outputs a digital value represented in redundant binary according to the magnitude relationship between the stage input voltage and two reference voltages, a higher and a lower reference voltages, and outputs a voltage obtained by subtracting the voltage corresponding to the digital output from the stage input voltage and doubled.

An AD conversion stage 20 coupled at a stage subsequent to the AD conversion stages 10 includes one or more AD conversion stages (not shown) which are coupled in cascade. The AD conversion stage(s) included in the AD conversion stage 20 may have a configuration similar to the AD conversion stages 10 or other configurations.

The digital correction circuit 30 controls the switch circuits 15 and 16 in each of the AD conversion stages 10 as appropriate and calculates a correcting value for correcting an error in analog input/output characteristics of the AD conversion stages 10. The digital correction circuit 30 receives digital outputs from the AD conversion stages 10 and 20, sums the outputs while shifting the bit locations of the outputs, and adds/subtracts the correcting value to/from the sum to generate an AD converted value of the pipeline AD converter.

### Calculation of Correcting Value

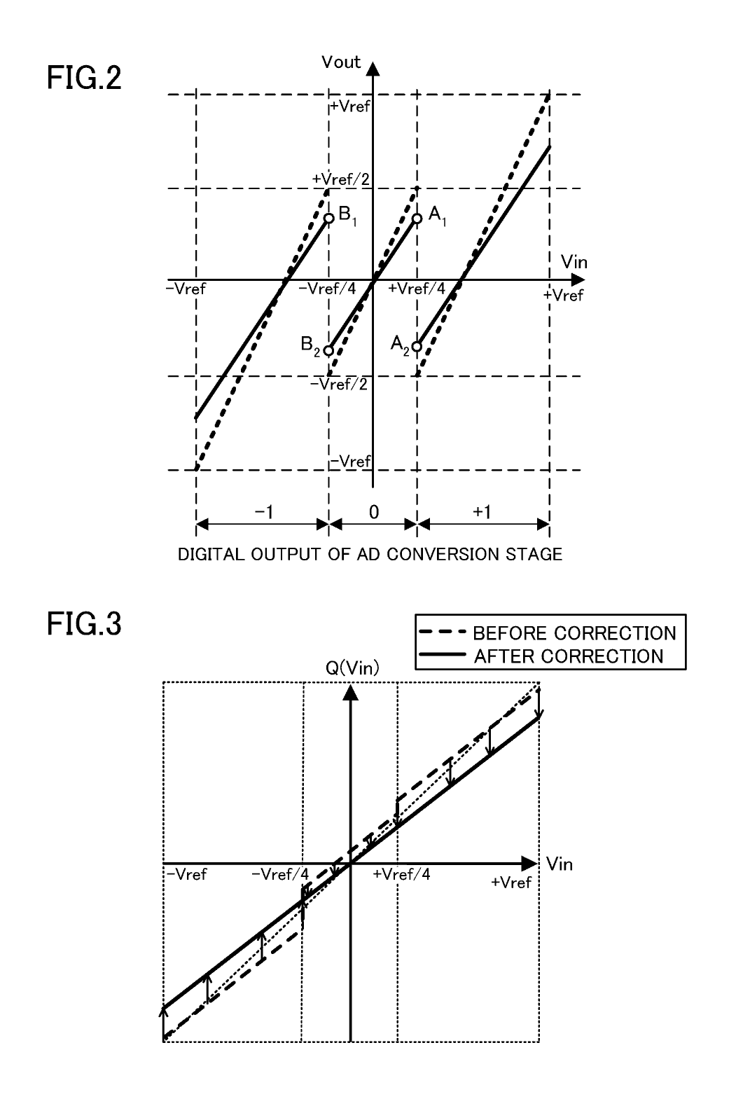

FIG. 2 illustrates analog input/output characteristics of the AD conversion stage 10. The horizontal axis represents a stage input voltage Vin, and the vertical axis represents a stage output voltage Vout. The transfer function, where elements included in the AD conversion stage 10 are under ideal conditions, is given by the following equation (1). The dashed lines in FIG. 2 represent the analog input/output characteristics.

$$Vout = 2 Vin - Vdac \\ Vdac = \{ \begin{matrix}- Vref & Vin < - Vref / 4 \\ 0 & - Vref / 4 \leq Vin \leq Vref / 4 \\ Vref & Vref / 4 < Vin\end{matrix} \qquad ( 1 )$$

However, actually, the analog input/output characteristics of the AD conversion stage 10 are as represented by the solid lines in FIG. 2 due to errors in the elements. Thus, an error occurs in the analog input/output characteristics of the AD conversion stage 10, and appears as an AD conversion error in the pipeline AD converter. That is, the input/output characteristics of the pipeline AD converter become nonlinear.

In order to correct the nonlinear error, a correcting value for correcting the error in the analog input/output characteristics of the AD conversion stage 10 is obtained. The correcting value can be calculated by obtaining digital values at points A1, A2, B1, and B2 in FIG. 2. Specifically, the digital correction circuit 30 controls the switch circuit 15 in the AD conversion stage 10 to be corrected (hereinafter referred to as a “target stage”) to select the DAC control signal output from the digital correction circuit 30, and controls the switch circuit 16 to select +Vref/4. In this state, a digital value DA1 at the point A1 is obtained from the AD converted value in subsequent AD conversion stages when the DAC control signal representing 0 is input, and a digital value DA2 at the point A2 is obtained from the AD converted value in the subsequent AD conversion stages when the DAC control signal representing +1 is input. Also, the digital correction circuit 30 controls the switch circuit 15 in the target stage to select the DAC control signal output from the digital correction circuit 30, and controls the switch circuit 16 to select −Vref/4. In this state, a digital value DB1 at the point B1 is obtained from the AD converted value in the subsequent AD conversion stages when the DAC control signal representing −1 is input, and a digital value DB2 at the point B2 is obtained from the AD converted value in the subsequent AD conversion stages when the DAC control signal representing 0 is input.

Where EA=DA1−DA2, and EB=DB1−DB2, the correcting value of the target stage is obtained from Dc in the following equation (2). Note that the argument of Dc is a value represented by the digital output of the target stage.

$$\begin{matrix}Dc ( - 1 ) = - EB \\ Dc ( 0 ) = 0 \\ Dc ( + 1 ) = + EA\end{matrix} \} \qquad ( 2 )$$

In conventional techniques, the correcting value is −EB when the digital output of the target stage is −1, and +EA when the digital output of the target stage is +1. On the other hand, the correcting value is 0, i.e., no correction is performed, when the digital output of the target stage is 0. In this case, however, an offset error in the AD conversion stage cannot be corrected. Thus, an AD conversion error in subsequent AD conversion stages at the time of inputting analog value 0 being as accurate as possible to the target stage is obtained, and the error is treated as a value for correcting an offset error. (See, for example, Japanese Patent Publication No. 2006-109403).

Where the equation (2) is transformed so that Dc (−1) and Dc (+1) have opposite signs, i.e., so that Dc (0) is the intermediate value between Dc (−1) and Dc (+1), the following equation (3) is obtained.

$$\begin{matrix}\begin{matrix}Dc ( - 1 ) = - \frac{EA + EB}{2} \\ Dc ( 0 ) = - \frac{EA - EB}{2}\end{matrix} \\ Dc ( + 1 ) = + \frac{EA + EB}{2}\end{matrix} \} \qquad ( 3 )$$

In the pipeline AD converter according to this embodiment, the correcting value is −(EA+EB)/2 when the digital output of the target stage is −1, −(EA−EB)/2 when the digital output of the target stage is 0, and +(EA+EB)/2 when the digital output of the target stage is +1. There is no need to input an analog value 0 to the target stage and calculate an error for correcting an offset error. Since the correcting values Dc (−1) and Dc (+1) have opposite signs, the digital correction circuit 30 may store either one of Dc (−1) or Dc (+1) in each of the AD conversion stages 10. Alternately, the digital correction circuit 30 may store the AD conversion errors EA and EB, and calculates the correcting value of the equation (3) when needed.

Note that the correcting value of the target stage is calculated based on AD conversion errors in subsequent AD conversion stages, and thus, each of the correcting values of the AD conversion stages 10 needs to be sequentially calculated from back to front. That is, when the correcting value of the AD conversion stage 10₁ is calculated, the error in the analog input/output characteristics of at least the AD conversion stage 10₂ needs to be corrected. When the correcting value of the AD conversion stage 10₂ is calculated, the error in the analog input/output characteristics of the AD conversion stage 20 needs to be corrected. Note that, if the error in the LSB of the AD converted value of the pipeline AD converter is ignorable, error correction in subsequent AD conversion stages (e.g., the AD conversion stage 20) may be omitted.

### Application of Correcting Value

The correcting value is applied while setting the AD conversion stage 10 to a normal operation mode. Specifically, the digital correction circuit 30 controls the switch circuit 15 in each of the AD conversion stages 10 to select the output from the encoder 13, and controls the switch circuit 16 to select the stage input voltage to bring the AD conversion stage 10 to a normal operation mode. When the correcting value is applied, the AD converted value Q (Vin) after correcting the input voltage Vin of the pipeline AD converter according to this embodiment is given by the following equation (4). Note that D₁(0) and D₂(0) are ideal AD conversion values when digital outputs of the AD conversion stages 10₁ and 10₂ are 0, respectively. D1 and D2 are digital outputs of the AD conversion stages 10₁ and 10₂, respectively. D₁c (D1) and D₂c (D2) are correcting values of the AD conversion stages 10₁ and 10₂, respectively (see the equation (3)). D3 is an AD converted value of the AD conversion stage 20.

Q(Vin)=D₁(0)+D₁c(D1)+D₂(0)÷D₂c(D2)+D3 (4)

Note that, where n AD conversion stages are coupled in cascade, the ideal AD conversion value Dₘ(0) of the m^{th} AD conversion stage is obtained by the following equation.

Dₘ(0)=2^{n-m}

According to this, D₁(0) and D₂(0) are as follows.

D₁(0)=2^{n 1}

D₂(0)=2ⁿ⁻²

FIG. 3 illustrates AD conversion characteristics of the AD conversion stage 10 before and after linearity correction. The horizontal axis represents the stage input voltage Vin. The vertical axis represents the AD converted value Q(Vin). Before the correction, gaps appear in the line representing the AD converted value at the points where Vin=±Vref/4 under the influence of the nonlinear error. Also, as can be seen from the conversion characteristics in the area where −Vref/4<Vin<+Vref/4, the conversion characteristics are as a whole, shifted upward under the influence of an offset error. To address this, when the correcting values obtained by the equation (3) is used, the nonlinear error and the offset error in the AD conversion stage 10 are corrected at once.

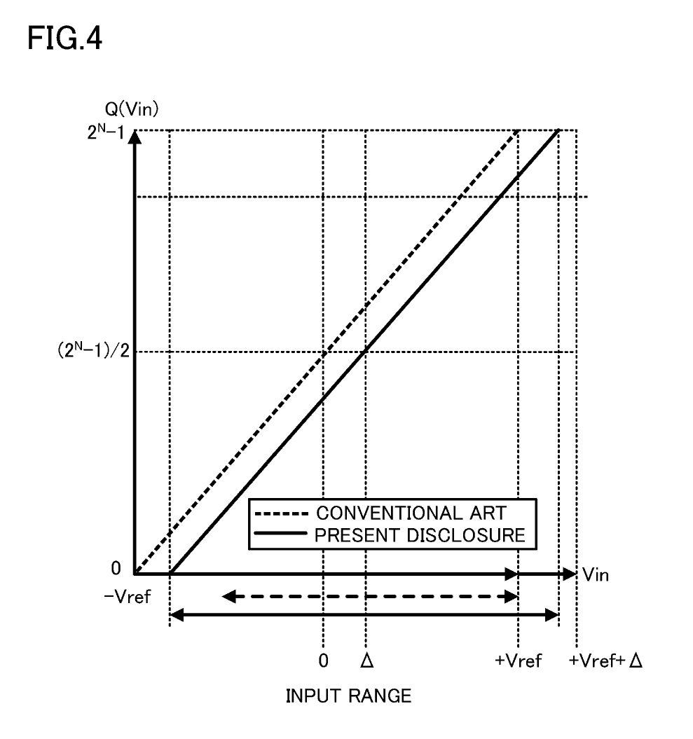

FIG. 4 illustrates AD conversion characteristics of the AD conversion stage 10 where an error occurs in a reference voltage. The horizontal axis represents the stage input voltage Vin. The vertical axis represents the AD converted value Q(Vin). In conventional techniques, even when an error occurs in a reference voltage, an analog input range is narrowed, since a median of an input voltage to an AD conversion stage is corrected to absolute analog value 0. By contrast, the pipeline AD converter according to this embodiment performs corrects a median of an analog input range of the AD conversion stage 10 to a median of a digital output range, thereby obtaining the analog input range.

As described above, according to this embodiment, an AD conversion error in a pipeline AD converter caused by errors in elements of an AD conversion stage or an error in a reference voltage can be corrected in the digital domain. In particular, an additional configuration and an additional step for inputting analog value 0 are not required. Furthermore, even when an error occurs in a reference voltage, an analog input range can be widely obtained.

Note that the number of the coupled AD conversion stages 10 is not limited two. More than two AD conversion stages 10 may be coupled in cascade to increase therefore, the bits of AD conversion of the pipeline AD converter.

### Second Embodiment

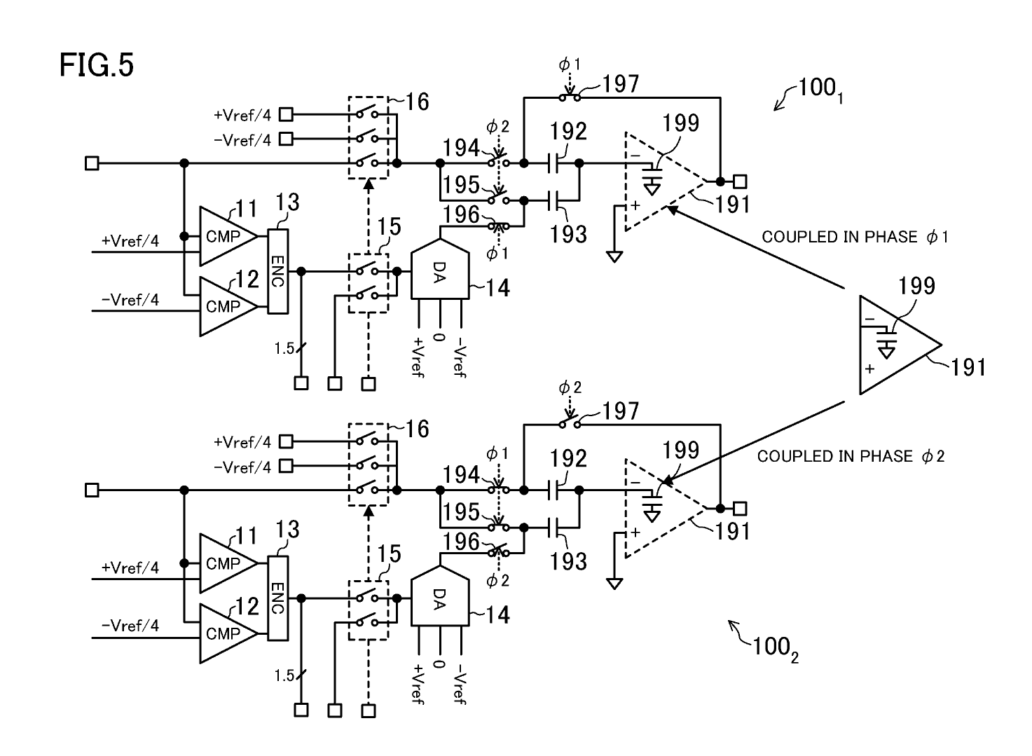

FIG. 5 illustrates a partial configuration of a pipeline AD converter with a shared amplifier according to a second embodiment. AD conversion stages 100 have almost the same configurations as the AD conversion stages 10 of FIG. 1. The section including an operational amplifier 191, capacitive elements 192 and 193, and switch circuits 194-197 corresponds to the difference circuit 17 and the amplifier circuit 18 in each of the AD conversion stages 10 of FIG. 1. The other elements are the same as those in the AD conversion stages 10 of FIG. 1. Although not shown, the pipeline AD converter according to this embodiment includes subsequent AD conversion stages coupled to the AD conversion stages 100 in cascade, and a digital correction circuit.

Each of the AD conversion stages 100 is controlled with two mutually exclusive clock signals φ1 and φ2. For example, in the AD conversion stage 100₂, in a phase φ1 where the clock signal φ1 is active, the switch circuits 194 and 195 are closed and the switch circuits 196 and 197 are open, thereby charging the capacitive elements 192 and 193 with a stage input voltage (hereinafter referred to as a “sampling operation”). On the other hand, in a phase φ2 where the clock signal φ2 is active, the switch circuits 194 and 195 are open and the switch circuits 196 and 197 are closed, thereby amplifying by a factor of two and outputting the residual voltage obtained by subtracting the output voltage of the DA converter 14 from the sampled stage input voltage (hereinafter referred to as a “calculation operation”). The AD conversion stage 100₁ operates in an opposite phase to the AD conversion stage 100₂. That is, when the AD conversion stage 100₂ performs a sampling operation, the AD conversion stage 100₁ performs a calculation operation. When the AD conversion stage 100₂ performs a calculation operation, the AD conversion stage 100₁ performs a sampling operation.

In each of the AD conversion stage 100, since the operational amplifier 191 may operate only during the calculation operation, it can be shared by the AD conversion stages 100₁ and 100₂, and can be used alternately by coupling the operational amplifier 191 to the stages phase by phase. Since the operational amplifier 191 is shared, the AD conversion stages 100₁ and 100₂ are substantially coupled in cascade. Note that FIG. 5 does not show any switch circuit for switching the coupling of the operational amplifier 191 for simplicity.

A parasitic capacitance 199 exists at an input of the operational amplifier 191. In a pipeline AD converter for single sampling as shown in the first embodiment, since a residual charge at the parasitic capacitance 199 can be reset in the sampling operation, no memory effect error occurs. However, in a pipeline AD converter with a shared amplifier as shown in this embodiment, one of the AD conversion stages 100 performs the sampling operation, while the other AD conversion stage 100 performs the calculation operation, and it is thus difficult to reset the residual charge at the parasitic capacitance 199. This causes a memory effect error such that the residual charge at the parasitic capacitance 199 is added to the calculation operation in the next phase. Therefore, in the pipeline AD converter according to this embodiment, the memory effect error is corrected in the digital domain as follows.

### Calculation of Correcting Value

The transfer function of the AD conversion stage 100 is given by the following equation (5). Note that A denotes a gain of the operational amplifier 191, Cs denotes electrostatic capacitance of the capacitive element 192, Cf denotes electrostatic capacitance of the capacitive element 193, Cp denotes electrostatic capacitance of the parasitic capacitance 199, and Voutx denotes a value Vout one phase, i.e., one clock earlier.

$$Vout = α \cdot Vin - β \cdot Vdac + γ \cdot Voutx \\ Vdac = \{ \begin{matrix}- Vref & Vin < - Vref / 4 \\ 0 & - Vref / 4 \leq Vin \leq Vref / 4 \\ Vref & Vref / 4 < Vin\end{matrix} \\ where \\ α = \frac{1 + \frac{Cs}{Cf}}{1 + \frac{Cs + Cf + Cp}{A \cdot Cf}} , β = \frac{\frac{Cs}{Cf}}{1 + \frac{Cs + Cf + Cp}{A \cdot Cf}} , \\ γ = \frac{\frac{Cp}{A \cdot Cf}}{1 + \frac{Cs + Cf + Cp}{A \cdot Cf}} \qquad ( 5 )$$

Where elements included in the AD conversion stage 100 are under ideal conditions, i.e., Cf=Cs, Cp=0, and A=∞, the equation (5) coincides with the equation (1), the analog input/output characteristics of the AD conversion stage 100 are represented by the solid lines in FIG. 2. However, actually, the analog input/output characteristics of the AD conversion stage 100 are as represented by the dashed lines in FIG. 2 due to errors in the elements. Furthermore, as can be seen from the equation (5), the analog output one clock earlier influences the analog output of the next clock cycle.

In order to correct the memory effect error, a correcting value for correcting the error in the analog input/output characteristics of the AD conversion stage 100 is obtained. The correcting value can be calculated by obtaining digital values at points A1 and A2 in FIG. 2. Specifically, a digital correction circuit (not shown) controls the switch circuit 15 in the target stage to select the DAC control signal output from the digital correction circuit, and controls the switch circuit 16 to select +Vref/4. In this state, the digital values DA1 and DA2 at the points A1 and A2 are obtained from the AD converted value in subsequent AD conversion stages when the DAC control signals representing 0 and +1 are input to the DA converter 14, respectively.

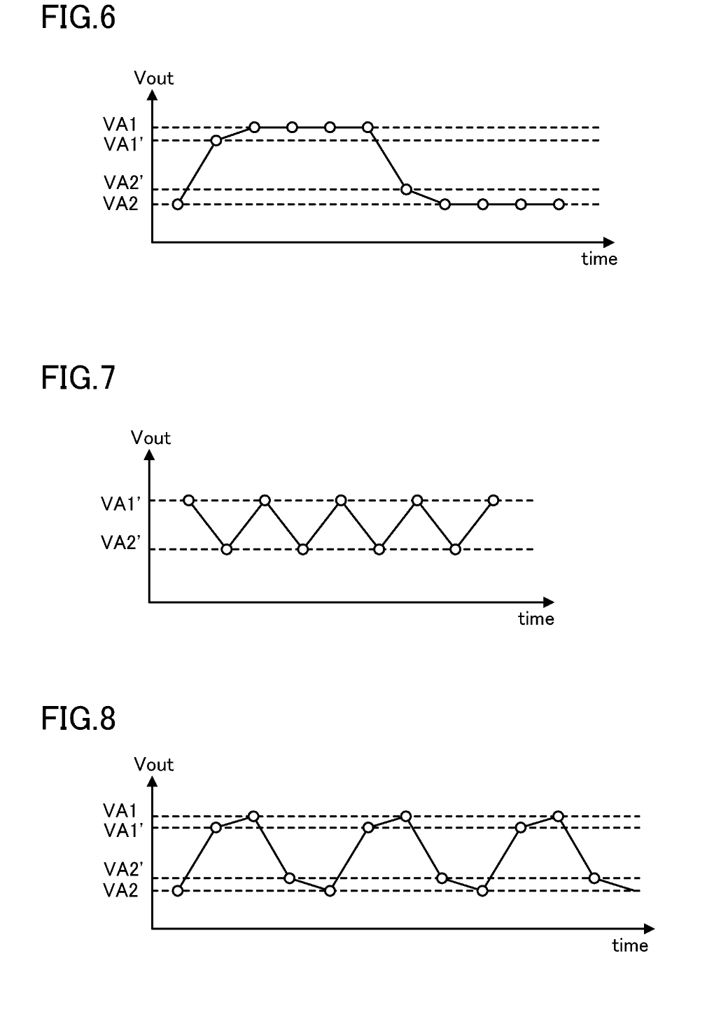

However, as shown in FIG. 6, immediately after the value represented by the DAC control signal is changed from +1 to 0 or from 0 to +1, the output voltage of the AD conversion stage 100 does not transit to VA1 or VA2, which is the original voltage of the point A1 or A2, but to VA1′ or VA2′ under the influence of the analog output one clock earlier. Thus, the digital values are obtained when two or more clock cycles have passed since the value represented by the DAC control signal was changed. As a result, the digital values DA1 and DA2 at the points A1 and A2 in FIG. 2 can be obtained where the output voltages of the AD conversion stage 100 are VA1 and VA2, respectively.

Output amplitude EA of the AD conversion stage 100 where the output voltage of the AD conversion stage 100 is changed in the pattern shown in FIG. 6 is given by the following equation (6).

EA=VA1−VA2=β·Vref+γ·(VA1−VA2)=β·Vref+γ·EA (6)

On the other hand, when the value represented by the DAC control signal is changed every one-clock cycle, the output voltage of the AD conversion stage 100 transits to VA1′ or VA2′ under the influence of the analog output one clock earlier, as shown in FIG. 7. As a result, the digital values DA1′ and DA2′ at the points A1 and A2 in FIG. 2 where the output voltages of the AD conversion stage 100 are VA1′ and VA2′ can be obtained.

Output amplitude EA′ of the AD conversion stage 100 where the output voltage of the AD conversion stage 100 is changed in the pattern shown in FIG. 7 is given by the following equation (7).

EA′=VA1′−VA2′=β·Vref+γ·(VA2′−VA1′)=β·Vref−γ·EA′ (7)

To sum up the equations (6) and (7), a coefficient γ for memory effect correction is obtained as follows.

$$γ = \frac{EA - {EA}^{′}}{EA + {EA}^{′}} \qquad ( 8 )$$

When EA and EA′ are represented by digital values (i.e., EA=DA1 −DA2, EA′=DA1′−DA2′), γ is also represented by a digital value. This enables correction of a memory effect error in the digital domain.

Alternatively, the value represented by the DAC control signal may be changed in every two clock cycles. In this case, the output voltage of the AD conversion stage 100 changes in the pattern shown in FIG. 8. Therefore, the digital value DA1′ or DA2′ is obtained in the first clock cycle after changing the value represented by the DAC control signal, and the digital value DA1 or DA2 is obtained in the second clock cycle.

The coefficient γ for memory effect correction may be calculated from the points B1 and B2 in FIG. 2. Although proof is omitted, γ is equal to the value obtained from the points A1 and A2.

Attention is to be paid when correcting a nonlinear error in addition to a memory effect error at the same time. This is because, as can be seen from the equation (6), EA itself in the correcting value Dc (see the equation (3)) for nonlinear error correction includes the term of γ, i.e., a memory effect error. Thus, EA not including the term of γ, i.e., β·Vref needs to be calculated. When the equation (6) is transformed, the following equation (9) is obtained.

β·Vref=EA·(1−γ) (9)

That is, when EA is multiplied by (1−γ), a nonlinear correcting value not including any memory effect error is obtained. This is also applicable to EB. When EB is multiplied by (1−γ), a nonlinear correcting value not including any memory effect error is obtained. Therefore, the correcting value of the equation (3) is corrected as shown in the following equation (10).

$$\begin{matrix}\begin{matrix}Dc ( - 1 ) = - \frac{EA + EB}{2} \cdot ( 1 - γ ) \\ Dc ( 0 ) = - \frac{EA + EB}{2} \cdot ( 1 - γ )\end{matrix} \\ Dc ( + 1 ) = + \frac{EA + EB}{2} \cdot ( 1 - γ )\end{matrix} \} \qquad ( 10 )$$

Application of Correcting Value

When the equation (5) is solved for Vin, the following equation (11) is obtained.

$$Vin = \frac{1}{α} ( Vout + β \cdot Vdac - γ Voutx ) \\ Vdac = \{ \begin{matrix}- Vref & Vin < - Vref / 4 \\ 0 & - Vref / 4 \leq Vin \leq Vref / 4 \\ Vref & Vref / 4 < Vin\end{matrix} \qquad ( 11 )$$

The right side of the equation (11) can be obtained from a result converted by the subsequent AD conversion stages except for α. Therefore, by performing correction based on the equation (11), highly accurate AD conversion characteristics can be provided. Note that α is almost 1, and no particular correction is thus required. If α is corrected, full-range correction in the digital domain may be performed.

The correcting value is applied while setting the AD conversion stage 100 to a normal operation mode. When the correcting value is applied, the AD converted value Q (Vin) after correcting the input voltage Vin of the pipeline AD converter according to this embodiment is given by the following equation (12). Note that D₁(0) and D₂(0) are ideal AD conversion values when digital outputs of the AD conversion stages 100₁ and 100₂ are 0, respectively. D1 and D2 are digital outputs of the AD conversion stages 100₁ and 100₂, respectively. D₁c (D1) and D₂c (D2) are correcting values of the AD conversion stages 100₁ and 100₂, respectively (see the equation (10)). γ₁ and γ₂ are coefficients for memory effect correction of the AD conversion stages 100₁ and 100₂, respectively. D₁x and D₂x are AD converted values of AD conversion stages subsequent to the AD conversion stages 100₁ and 100₂ one clock earlier, respectively. D3 is an AD converted value of the subsequent AD conversion stages.

Q(Vin)=D₁(0)+D₁c(D1)−γ₁·D₁x+D₂(0)+D₂c(D2)−γ₂·D₂x+D3 (12)

As described above, according to this embodiment, a memory effect error in a pipeline AD converter with a shared amplifier can be corrected in the digital domain. Furthermore, a nonlinear error and an offset error are also corrected at once.

Note that in a pipeline AD converter for double sampling including the AD conversion stages 100₁ and 100₂ which are coupled in parallel, a memory effect error, a nonlinear error and an offset error in the digital domain can be corrected by calculating the coefficient γ for the memory effect correction by the above-described means.

What is claimed is:

1. A pipeline AD converter comprising:
a plurality of cascade-coupled AD conversion stages, each configured to output as a digital output, a value represented in redundant binary according to a magnitude relationship between an input voltage and two reference voltages, a higher and a lower reference voltages, and to output a voltage obtained by subtracting a voltage corresponding to the digital output from the input voltage and doubling; and
a digital correction circuit configured to calculate AD conversion errors EA and EA′ in AD conversion stages subsequent to a target stage which is one of the plurality of AD conversion stages and alternately uses a common operational amplifier with another AD conversion stage, EA being an error between an AD conversion result when two or more clock cycles have passed after setting the digital output of the target stage to 0, and an AD conversion result when two or more clock cycles have passed after setting the digital output of the target stage to +1 in a state where the higher reference voltage is input to the target stage, EA′ being an error between an AD conversion result when the digital output of the target stage is changed from +1 to 0, and an AD conversion result when the digital output of the target stage is changed from 0 to +1 in a state where the higher reference voltage is input to the target stage; and to subtract a correcting value of the target stage from the digital output of the target stage, the correcting value being a value obtained by multiplying an output from the AD conversion stages subsequent to the target stage one clock earlier by (EA−EA′)/(EA+EA′).

2. The pipeline AD converter of claim 1, wherein
the digital correction circuit calculates an AD conversion error EB in the AD conversation stages subsequent to the target stage, EB being an error between an AD conversion result when two or more clock cycles have passed after setting the digital output of the target stage to 0, and an AD conversion result when two or more clock cycles have passed after setting the digital output of the target stage to −1 in a state where the lower reference voltage is input to the target stage, and to add a correcting value of the target stage to the digital output of the target stage, the correcting value being −(EA+EB)(1−γ)/2 when the digital output of the target stage is −1, −(EA−EB)(1−γ)/2 when the digital output of the target stage is 0, and +(EA+EB)(1−γ)/2 when the digital output of the target stage is +1, where γ=(EA−EA′)/(EA+EA′).

3. The pipeline AD converter of claim 1, wherein
the digital correction circuit calculates the AD conversion error EA′ by switching the digital output of the target stage every one-clock cycle.

4. A pipeline AD converter comprising:
a plurality of cascade-coupled AD conversion stages, each configured to output as a digital output, a value represented in redundant binary according to a magnitude relationship between an input voltage and two reference voltages, a higher and a lower reference voltages, and to output a voltage obtained by subtracting a voltage corresponding to the digital output from the input voltage and doubling; and
a digital correction circuit configured to calculate AD conversion errors EA and EB in AD conversion stages subsequent to a target stage which is one of the plurality of AD conversion stages, EA being an error between an AD conversion result when the digital output of the target stage is set to 0, and an AD conversion result when the digital output of the target stage is set to +1 in a state where the higher reference voltage is input to the target stage, EB being an error between an AD conversion result when the digital output of the target stage is set to 0, and an AD conversion result when the digital output of the target stage is set to −1 in a state where the lower reference voltage is input to the target stage, and to add a correcting value of the target stage to the digital output of the target stage, the correcting value being −(EA+EB)/2 when the digital output of the target stage is −1, −(EA−EB)/2 when the digital output of the target stage is 0, and +(EA+EB)/2 when the digital output of the target stage is +1.

5. A method of correcting an output from a pipeline AD converter including a plurality of cascade-coupled AD conversion stages, each configured to output as a digital output, a value represented in redundant binary according to a magnitude relationship between an input voltage and two reference voltages, a higher and a lower reference voltages, and to output a voltage obtained by subtracting a voltage corresponding to the digital output from the input voltage and doubling, the method comprising:
calculating an AD conversion error EA in AD conversion stages subsequent to a target stage which is one of the plurality of AD conversion stages and alternately uses a common operational amplifier with another AD conversion stage, EA being an error between an AD conversion result when two or more clock cycles have passed after setting the digital output of the target stage to 0 and, an AD conversion result when two or more clock cycles have passed after setting the digital output of the target stage to +1 in a state where the higher reference voltage is input to the target stage;
calculating an AD conversion error EA′ in the AD conversion stages subsequent to the target stage, EA′ being an error between an AD conversion result when the digital output of the target stage is changed from +1 to 0, and an AD conversion result when the digital output of the target stage is changed from 0 to +1 in a state where the higher reference voltage is input to the target stage; and
subtracting a correcting value of the target stage from the digital output of the target stage, the correcting value being a value obtained by multiplying an output from the AD conversion stages subsequent to the target stage one clock earlier by (EA−EA′)/(EA+EA′).

6. The method of claim 5, further comprising:
calculating a AD conversion error EB in the AD conversion stages subsequent to the target stage, EB being an error between an AD conversion result when two or more clock cycles have passed after setting the digital output of the target stage to 0, and an AD conversion result when two or more clock cycles have passed after setting the digital output of the target stage to −1 in a state where the lower reference voltage is input to the target stage; and
adding a correcting value of the target stage to the digital output of the target stage, the correcting value being −(EA+EB)(1−γ)/2 when the digital output of the target stage is −1, −(EA−EB)(1−γ)/2 when the digital output of the target stage is 0, and +(EA+EB)(1−γ)/2 when the digital output of the target stage is +1, where γ=(EA−EA′)/(EA+EA′).

7. The method of claim 5, wherein
in calculating the AD conversion error EA′, the AD conversion error EA′ is calculating by switching the digital output of the target stage every one-clock cycle.

8. A method of correcting an output of a pipeline AD converter including a plurality of cascade-coupled AD conversion stages, each configured to output as a digital output, a value represented in redundant binary according to a magnitude relationship between an input voltage and two reference voltages, a higher and a lower reference voltages, and to output a voltage obtained by subtracting a voltage corresponding to the digital output from the input voltage and doubling, the method comprising:
calculating an AD conversion error EA in AD conversion stages subsequent to a target stage which is one of the plurality of AD conversion stages, EA being an error between an AD conversion result when the digital output of the target stage is set to 0, and an AD conversion result when the digital output of the target stage is set to +1 in a state where the higher reference voltage is input to the target stage;
calculating a AD conversion error EB in the AD conversion stages subsequent to the target stage, EB being an error between an AD conversion result when the digital output of the target stage is set to 0, and an AD conversion result when the digital output of the target stage is set to −1 in a state where the lower reference voltage is input to the target stage; and
adding a correcting value of the target stage to the digital output of the target stage, the correcting value being −(EA+EB)/2 when the digital output of the target stage is −1, −(EA−EB)/2 when the digital output of the target stage is 0, and +(EA+EB)/2 when the digital output of the target stage is +1.
